(19) United States
(12) Patent Application Publication
(10) Pub. No.: US 2009/0183900 A1
(43) Pub. Date: Jul. 23, 2009

(54) Anti-static Spacer for High Temperature Curing Process of Flexible Printed Circuit Board

(76) Inventors: Kwang Suck Suh, Kyungki-do (KR); Jong Eun Kim, Seoul (KR); Tae Young Kim, Seoul (KR)

Correspondence Address: PARK LAW FIRM, 3255 WILSHIRE BLVD, SUITE 1110, LOS ANGELES, CA, 90010, US

(21) Appl. No.: 11/813,615

(22) PCT Filed: Jan. 9, 2006
(86) PCT No.: PCT/KR2006/000084

§ 371 Date: Jul. 10, 2007

(30) Foreign Application Priority Data
Jan. 10, 2005 (KR) 10-2005-0002188

(51) Int. Cl. H05K 1/00; H05F 3/00

(52) U.S. Cl. 174/254; 361/220

(57) ABSTRACT

The present invention relates to a spacer for a flexible printed circuit board used in a high temperature process. In particular, in the spacer formed with a permanent anti-static layer for the flexible printed circuit board used in the high temperature process of the present invention, the anti-static layer is formed by coating an anti-static solution comprising a metal oxide, an organic or inorganic binder, and additives for supplying a releasing property, as effective ingredients, and drying it to thereby provide the permanent anti-static property and the releasing property on the surface of the spacer, and the spacer can be used at a high temperature process. The spacer of the present invention is not a spacer for use in general delivery, which can be used in room temperature, and the spacer of the present invention can be used at a high temperature of above 150° C., and does not produce black impurities, and further has the releasing property for preventing the separation of the solder resist of the flexible printed circuit board during the high temperature process.

### TECHNICAL FIELD

The present invention relates to an anti-static spacer for a flexible printed circuit board used in a high temperature curing process, and more in particular, to such an anti-static spacer used in a high temperature curing process, in which the spacer is heated at a high temperature of approximately 150° C. to bond an integrated circuit chip onto the flexible printed circuit board.

### BACKGROUND ART

According to the recent trends of fabricating electronic parts compact and light-weight, a flexible printed circuit board is widely used as a new type of printed circuit board in the fabrication of the terminals, and the like used in a mobile communication, a personal digital assistant (PDA), and other use purposes. The process of fabricating such flexible printed circuit board comprises bonding an integrated circuit chip (LCD Drive IC) onto a high temperature polymer film such as a polyimide, and attaching necessary electronic parts on it. Most of the recent LCD display panels for mobile phones, and several liquid crystal display devices, and the like employ such a flexible printed circuit board.

A chip for driving the liquid crystal is mounted on the surface of the flexible printed circuit board. This flexible printed circuit board is delivered to the users by winding on a reel. At this time, the IC chip with sharp edge and corners can scratch the other surface of the film, causing a generation of undesired particles. To avoid this problem, flexible printed circuit board is delivered after wound on a reel along with a spacer

The spacers can be classified into two types: One is used for delivery and the other is for process lines. The fabrication process of the spacer for the delivery is comprised of forming an anti-static layer on both surfaces of polymer films such as polyester film, cutting the film by a desired width, and embossing shapes of desired height at both edges thereof. In this regard, in order to fabricate the anti-static spacer for the delivery, a polymer film which is formed with a conductive polymer layer on the surface of the polyester by means of using a solution coating method, in which conductive polymer is coated as an anti-static agent, a gas phase polymerization method, or the like is used.

Such a fabrication process for the spacer using the method of forming the conductive polymer layer is improper for fabricating the spacer for the process line. In general, the spacer for the process is used for curing the flexible printed circuit board at a high temperature of about 150˜160° C. for 30 minutes to 3 hours to mount the chip on the surface of the flexible printed circuit board. Accordingly, the polymer film for the spacer is selected from high temperature heat-resistant films such as a polyimide, a polyether-imide, polyphenyloxide and the like, and the component for the anti-static layer should endure the high temperature for a long period of time. In this case, when the conductive polymers are heated up to 150˜170° C., they eventually lose their antistatic properties because of the degradation of conductive polymer.

Conventionally, the spacer for high temperature processes has been fabricated by coating carbon black dispersed conductive solution on both surfaces of the base films, or a plain polyimide film has been used as it is without any anti-static treatment. As a result, thus prepared spacers are known to cause several problems as follows. First, in case of using the film without any anti-static treatment, dusts are collected on the surface of the spacer or the printed circuit board due to the electrostatic attraction force formed on the surface of the spacer, resulting in a failure of the fabricated printed circuit board. Second, in case of the spacer formed with carbon black dispersed conductive solution, black particles containing carbon black come off from the surface of the spacers, resulting in a problem such as breakdown failure upon sitting on the micro patterns of the flexible printed circuit board.

As described previously, when the spacer is used together with flexible printed circuit board, it inevitably comes into contact with the surface of flexible circuit board with the outer surface which is a so-called solder resist. In this case, the spacer and solder resist layer of flexible circuit board adhere to each other, so that, in many cases, the solder resist layer is peeled off and stick on the surface of the spacer.

Because the conventional methods are improper for use as the spacer for the curing process, there is a need for a novel type of spacer for the high temperature process, which can maintain the anti-static property at high temperatures of 150-170° C. for at least several hundreds of hours, and which does not generate black particles, and which does not adhere with solder resist of the flexible printed circuit board.

### [Disclosure]

### [Technical Problem]

Therefore, the present invention has been made to solve the problems occurring in the conventional arts, and it is a primary object of the present invention to provide an anti-static spacer for a high temperature process, which can be used in a curing process of the flexible printed circuit board, in particular, which can maintain the anti-static property and does not produce black particles, even upon the repeated use at temperatures of 150-170° C. for a long period of time.

Another object of the present invention is to provide a spacer possessing good enough releasing property from solder resist layer for a high temperature process of the flexible printed circuit board.

### [Technical Solution]

The spacer formed with a permanent anti-static layer for a flexible printed circuit board used in a high temperature process according to the present invention can be fabricated by coating and drying an anti-static coating solution, which comprises effective ingredients such as one or more metal oxides and one or more organic and/or inorganic binders, or besides an releasing agent for imparting releasing property, on surface of a film made of high temperature polymers, to produce an anti-static polymer film, cutting it to a predetermined width, and embossing both edges of the cut film.

The anti-static coating solution for the high temperature process of the present invention is fabricated by mixing 3 to 30 parts by weight of a metal oxide, 5 to 30 parts by weight of an organic or inorganic binder, 0.1 to 2 parts by weight of thickener and 38 to 91.9 parts by weight of a solvent.

Alternatively, in order to impart easy release of the spacer from solder resist, the anti-static coating solution for the high temperature process of the present invention can be fabricated by mixing 3 to 30 parts by weight of a metal oxide, 5 to 30 parts by weight of an organic or inorganic binder, 0.05 to 1.0 parts by weight of an additive to provide easy releasing property, 0.1 to 2 parts by weight of a thickener, and 37 to 91.85 parts by weight of a solvent.

With regard the contents of the respective ingredients of the coating solution, if their concentrations are below the said minimum content, the effect of the contained ingredient are slight, and if their concentrations are above the said maximum content, the effect of the contained ingredients are not considerable or they act as impurities to reduce the adhesion of the coated anti-static layer or to reduce the physical property of the produced coating.

The metal oxide applicable to the present invention comprises an indium oxide, a tin oxide, a zinc oxide, a titanium oxide, and the like. Also, the particle size of the metal oxide is preferable in a nanometer level not more than 2 μam. In this regard, when the particle size becomes smaller, it shows the same anti-static property even at low concentrations and reduces the scattering of incident light, thereby improving the transparency. Further, the metal oxides themselves having conductivity of 10⁻¹˜10⁵ Ω · cm or those doped with other chemical such as arsenic are applicable. The shape of metal oxides can be spherical, fiber or flake with an aspect ratio of higher than 1. Moreover, the metal oxides dispersed in solvents such as water, alcohols, toluene, ethylacetate, MEK, xylene and the like can be used in the present invention. In particular, metal oxides dispersed in solvents are more effective in the present invention, because additional dispersion after surface modification is not necessary to prepare the coating solutions.

With regard to the organic or inorganic binders applicable to the present invention, it is possible to use one or more organic binders having a functional group such as urethane group, acryl group, ester group, epoxy group, amide group, imide group, hydroxyl group, carboxyl group, styrene group, carbonate group, vinyl-acetate group, and the like, or to use copolymer binder, which has been made by co-polymerizing more than one functional group, such as an ester-ether, an acryl-urethane, an acryl-epoxy, an urethane-epoxy, and the like. As for the binders such as the urethane, the acryl, the epoxy and the amide, and the like, when such curing agents as melamines, isocyanates, weak acids, and the like can be used to impart the better physical properties of the coated layers. Post-curing after coating and drying can be applied to impart strong mechanical properties of the coated layers. Alternately, inorganic binders such as various types of silicates, titanates, and the like can be used alone or in the form of a mixture with organic binders. Especially, if the organic binder and the inorganic binder are used in a mixed form, it is possible to fabricate the anti-static coating solution, which can impart flexibility and thermal resistance to the coated layer, because the organic binder can provide the flexibility, and the inorganic binder can provide high temperature durability. If the silicate or titanate compound has been used alone or by mixing with the organic binder after a sol solution has been made from the hydrolysis of the solution previously, when they are cured by post-curing process, that is, they have been cured for 12-60 hours in an oven heated at 40-60° C. after the coating on base films, it is possible to improve the physical property of the coating film as the curing process progresses gradually.

When the conductive material is coated using binder , it is possible to use the single binder alone, or by mixing any of them among the above binders, if considering the long term heat resistant property only. In this regard, if it is required to apply the releasing property, the binder can act an important role in application of the releasing property, by comparing the used solder resist and the ingredients carefully and selecting it.

Further, additives can be used to prevent a sticking problem between the spacer and the solder resist of the flexible printed circuit board. These additives migrate onto the surface after coating and increase the releasing property. These releasing agents can be selected from any one of a fluorine group, a silicon group, an ethylene-oxide group, or by mixing such ingredients. However, when such releasing agents have been used too much, it can bloom out to the surface too much, so that they can act as impurities.

Therefore, it is important to maintain optimum contents according to the present invention.

As for the solvent used in the present invention, it can be used differently depending on the types of the organic or inorganic binders, and organic solvents such as toluene, methyletherketon, ethylacetate, butylacetate, xylene, and the like, water, or alcoholic solvents such as, methyl alcohol, ethyl alcohol, isopropyl alcohol can be used.

In order to form the antistatic layer comprising metal oxides as an effective ingredient, almost all of the conventional coating methods such as spraying method, electro-plating, dipping method, roll coating method, bar coating method, gravure method, and reverse gravure method, and the like can be used. In this regard, it is possible to form a physically strong anti-static layer when the coated film is cured with drying for 1 to 30 minutes at a temperature of 50 to 150° C. after the coating process.

If the anti-static layer is required to have pencil hardness of more than 1 H, and if it is required to have rubbing off resistance to organic solvents such as an alcohol group, and the like, it is advantageous to use a method for forming the anti-static layer by means of an ultraviolet curing method. To this end, ultraviolet ray curable resins and photo-initiators can be used as a mixture with metal oxides.

This UV curable coating solution comprising the metal oxide as effective ingredient is prepared by mixing 3 to 30 parts by weight of metal oxide, 5 to 30 parts by weight of UV curable binder composed of 2 to 15 functional acrylate/methacrylate oligomers, 1 to 6 functional group acrylate/metacrylate monomer, and photo-initiator, 0.05 to 1.0 parts by weight of releasing agent, 0.1 to 2 parts by weight of thickener, and 37 to 92 parts by weight of solvent.

The solid contents and the viscosity of the coating solution should be controlled so that the thickness of the coating layer of the anti-static layer formed on the surface by a thermal curing method or an UV curing method could be 0.02 to 2 μm after drying. In this regard, it is advantageous if the viscosity of the coating solution is controlled to be 10 to 1,000 cps, and the solid contents of the coating solution is controlled to be 0.5 to 40%. When the thickness of the conductive polymer coating layer is below 0.02 μm, it becomes difficult to obtain the uniform anti-static effect, and when the thickness of the conductive polymer coating layer is above 2 μm, it becomes undesirable because the extent of increasing the anti-static effectiveness becomes slight.

Further, in the case where the anti-static coating solution comprising the metal oxide as an effective component is coated on the surface of the heat-resistant polymer film, when the surface tension of the polymer substrates is too much different from that of effective ingredients and solvents of the coating solution, coating solution does not wet enough to provide an uniform coating layer and strong adhesion of coated layer on the substrates. Therefore, it is advantageous to increase the wetting and the adhesion of the coating solution if the surface tension and polarity of the polymer substrates is low. In this case, a corona treatment is recommended to provide the surface tension of higher than 35 dynes/cm². A coating of primer such as Nipollan, Takeda, Japan and the like having a strong adhesion with substrates is recommended, prior to the coating of the antistatic solution of the present invention, to provide excellent wetting and adhesion of the coating solution.

As the present invention relates to a spacer for high temperature process, it is preferable to use polymer materials which have a high heat-resistant property enough to withstand the high temperature process, for example, a polyimide, a polyether-imide, a polyphenylene oxide, a polyether sulfone, high temperature polycarbonate and the like, the heat resistant temperature of which is above 150° C., and which can be used for the high temperature process. However, the present invention can be applied to general polymer film made of materials having heat-resistant temperature lower than that of the above materials, such as various forms of polyesters, a polybutylene-terephthalate, a polyethylene-naphthalate, a polycarbonate, an cyclo olefinic compound, a polystyrene, and the like.

### [Advantageous Effects]

Accordingly, according to the present invention, the spacer fabricated by forming the anti-static layer comprising the metal oxide and the organic and/or inorganic binders as effective ingredients on surface of the high temperature polymer substrates which can withstand high temperature process of 150° C., provides releasing property, and creates no particle impurities, without deteriorating anti-static properties.

Further, when the proper releasing agent is used along with the above said ingredients, the spacer does not adhere to the solder resist of the flexible printed circuit board.

### DESCRIPTION OF DRAWINGS

FIG. 1 is a perspective view showing a spacer for a flexible printed circuit board used in the high temperature curing process according to the present invention.

FIG. 2 is a partial cross-sectional view of an embossing shown in FIG. 1.

FIG. 3 is a perspective view showing a spacer for a flexible printed circuit board used in the high temperature curing process according to another embodiment of the present invention.

FIG. 4 is a partial cross-sectional view of an embossing shown in FIG. 3.

### MODE FOR INVENTION

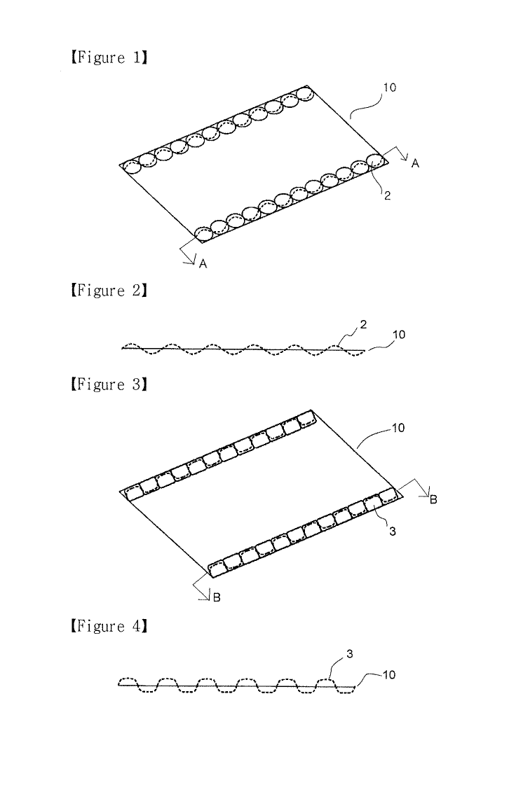

Hereinafter, the present invention will be explained in detail with reference to the appended drawings. It is required to form a round-shaped rugged portion on both edge surfaces of a spacer, as is for the general spacer for delivery, in case of fabricating the spacer formed with the anti-static layer comprising the metal oxides as effective ingredients. This is called an embossing process, and an example of the rugged portion is shown in FIGS. 1 and 2. FIG. 1 is a perspective view showing a spacer for a flexible printed circuit board used in the high temperature process according to the present invention, and FIG. 2 is a cross-sectional view taken along the line A-A of FIG. 1. As shown in FIG. 1, the round-shaped rugged portion 2 formed at the edge of the spacer 10 acts to protect the flexible printed circuit board. Another example of the rugged portion is shown in FIG. 3 and FIG. 4. FIG. 3 is a perspective view showing a spacer 10 formed with a square-shaped rugged portion 3 for the flexible printed circuit board used in the high temperature process according to another embodiment of the present invention, and FIG. 4 is a cross-sectional view taken along the line B-B of FIG. 3. The rugged portion can be formed as a round shape as well as a square shape depending on the requirement of the user. While the round shaped rugged portion is advantageous because a surface contacting with the flexible printed circuit board becomes to be the smallest, in case of the square-shaped rugged portion, it is stable because it supports the printed circuit board over a long length although a contacting surface of an end portion is small.

The round-shaped rugged portion can be fabricated by using a round-shaped mold or a planar shaped mold. In case of the round-shaped mold, it is required to make a round-shaped device having a size shown in FIG. 1 on the surface of the round metal member. Further, in case of the planar mold, it is required to make a round-shaped device for forming the rugged portion on the long stick shaped metal member. Also, it is required to mount a heating device to the round-shaped mold. In this regard, it is necessary to apply a temperature of about 150° C. to 400° C. to form the round-shaped rugged portion on a polyimide film. When the film passes through the device, it is possible to form the round-shaped rugged portion by using heat and pressure.

In order to increase the productivity, several spacers can be fabricated simultaneously by forming several round-shaped rugged portions at a time, which is the embossing, followed by the slitting.

Also, as the spacer for the high temperature process, which has been fabricated by the method described above, will be used at high temperatures for a long time period, it is preferable to carry out a setting procedure of maintaining the shape by carrying out an annealing after carrying out the embossing.

Hereinafter, the present invention will be described in detail with reference to the embodiments. However, the embodiments are not intended to limit the scope of the present invention.

### COMPARATIVE EXAMPLE 1

4g of a polyethylene-dioxy-thiophene water dispersed solution, 9 g of an urethane group binder having a molecular weight of 10,000, 0.1 g of zonyl additive (Dupon Inc.), 0.2 g of ethylene-glycol, and 0.2 g of 1-methyl-2-pyrolidinone were added into 25 g of a mixed solvent made by mixing an ethyl-alcohol and an isopropyl-alcohol in a volume ratio of 1:1 and mixed them to fabricate a conductive coating solution, and it was coated on the polyimide film having a thickness of 125 μm by a thickness of 0.5 μm, and then the coated film was dried for 2 minutes at a temperature of 80° C. Then, a spacer was fabricated at a temperature of 300° C. by using the film fabricated by the above technique.

As a result of measuring the surface resistance of the embossed polyimide spacer by means of a well-known method, the surface resistance was observed to be 10⁵ Ω/area. The measured results of the change of the surface resistance according to the lapse of the time after applying the spacer to a temperature of 150° C. was shown in table 1. As shown in table 1, when 72 hours have passed at a temperature of 150° C., the surface resistance have increased up to above 10¹² Ω/area to thereby loss the ant-static property and be changed into an insulating property(see table 1).

### COMPARATIVE EXAMPLE 2

Comparative example 2 was intended to check if there was any mutual attachment between the spacer and the flexible printed circuit board during the high temperature process in a state where the spacer and the flexible printed circuit board were overlapped. The spacer was fabricated by a polyimide without any treatment at 300° C., was overlapped with the flexible printed circuit board, and was left to stand at 150° C. for 3 hours. Thereafter, the overlapped spacer and flexible printed circuit board was drawn out and separated into two layers. In this instance, it was estimated if there was any portion where the solder resist component on the surface of the flexible printed circuit board were peeled off.

As an estimation result, almost all of the solder resist on the surface of the flexible printed circuit board was peeled off toward the spacer.

### COMPARATIVE EXAMPLE 3

Comparative example 3 is identical to comparative example 2 except that the spacer was fabricated by using a film characterized by forming the anti-static layer comprising the conductive polymers as effective ingredients on the surface of the polyimide film.

As an estimation result, with regard to the peeling off of the solder resist on the surface of the flexible printed circuit board toward the spacer, it was much improved in comparison with the comparative example 2.

However, the solder resist having about 10% of the area was still peeled off toward the spacer.

TABLE 1
a table confirming the heat-resistant property of the spacer fabricated
by using the conductive polymer according to the conventional art

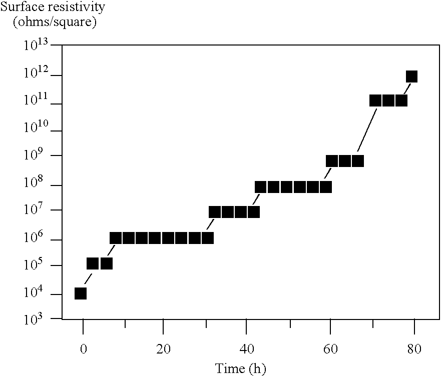

### EXAMPLE 1

Example 1 is intended to confirm whether or not the initial surface resistance was maintained even if the spacer was left to stand for a long time period at a temperature of 150° C. A spacer formed with an anti-static layer having a thickness of 1.0 cm was fabricated by coating an anti-static solution on the surface of a polyimide film having a thickness of 125 Mm and drying it. In this regard, the coating solution was fabricated by mixing 2.5 g of doped tin oxide dispersed solution, and 2.5 g of acrylic urethane binder, with 3 g of water and 5 g of isopropyl-alcohol.

The surface resistance of the spacer fabricated by the above technique was measured to be 10⁷ Ω/area. The surface resistances observed periodically from the spacer was represented in table 2. In this regard, the spacer was heated in an air convection oven at 150° C. for up to 500 hours. As represented in Table 2, the initial surface resistance of 10⁷ Ω/area of the spacer was maintained as it was, although the spacer was left to stand in the oven at a temperature of 150° C. for up to 500 hours (confer table 2)

### EMBODIMENT EXAMPLE 2

Embodiment example 2 is intended to search if there was any mutual attachment between the spacer and the flexible printed circuit board during the high temperature process in a state where the spacer and the flexible printed circuit board were overlapped. A spacer formed with an anti-static layer having a thickness of 1.0 μm was fabricated by spraying an anti-static coating solution on the surface of a polyimide film having a thickness of 125 μm and drying it. In this regard, the coating solution was fabricated by mixing 2.5 g of doped tin oxide dispersed solution, 2.5 g of acrylic urethane binder, and 0.05 g of silicone mold releasing agent (Shinetsu Inc.), with 3 g of water and 5 g of isopropyl-alcohol.

The surface resistance of the spacer fabricated by the above technique was measured to be 10⁷ Ω/area. Also, it can be seen that the solder resist on the surface of the flexible printed circuit board was not peeled off toward the spacer at the time of high temperature heat treatment, because the surface of the spacer was clean when the spacer and the flexible printed circuit board were arranged to overlap after being left to stand at a temperature of 150° C. for 3 hours and then they were drawn out and two film layers were separated from each other.

### EMBODIMENT EXAMPLE 3

Embodiment example 3 is intended to confirm the existence of the heat resistant property and the releasing property of the spacer formed with the anti-static layer by using the ultraviolet ray curing type binder. First, a primer layer was formed on the polyimide film to a thickness of 0.5 μm by coating a Nipollan adhesive with a curing agent at a ratio of 10:2. Then, a spacer was fabricated by coating an anti-static solution on the primer layer formed on the surface of the polyimide film having a thickness of 125 μm and drying it to be a thickness of 1.0 μm, and then it was cured by means of the ultraviolet ray by applying energy of 500 mJ. In this regard, the anti-static coating solution was fabricated by mixing 1.5 g of the doped tin oxide dispersed solution, 2 g of 6 functional group acrylate oligomer, 0.5 g of 3 functional group acrylate monomer, 0.1 g of initiator, and 0.05 g of the silicone mold releasing agent (Shinetsu Inc.), with 4 g of isopropyl-alcohol and 4 g of ethylene-glycol-mono-methylether.

The surface resistance of the spacer fabricated by the above technique was measured to be 10⁸ Ω/area. Also, it can be seen that the solder resist on the surface of the flexible printed circuit board was not peeled off toward the spacer at the time of high temperature heat treatment, because the surface of the spacer was clean when the spacer and the flexible printed circuit board were arranged to overlap after being left to stand at a temperature of 150° C. for 3 hours and then they were drawn out and two film layers were separated from each other.

TABLE 2
a table confirming the heat resistant property of the spacer
formed with an anti-static layer by using the metal
oxide according to the present invention

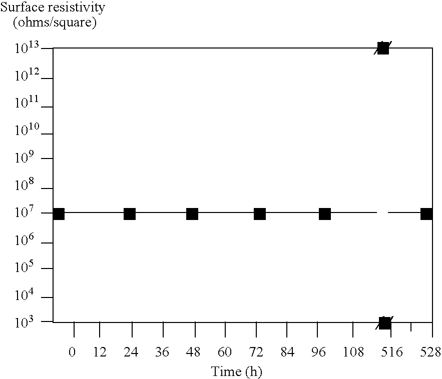

### INDUSTRIAL APPLICABILITY

Accordingly, the spacer for the permanent anti-static flexible printed circuit board used in the high temperature process according to the present invention can be used to protect the flexible printed circuit board at the time of fabricating it for the terminals used in mobile communication, personal digital assistant (PDA), and the like, because it maintains antistatic properties even after a high temperature curing process along with flexible printed circuit boards.

1: A transparent permanent anti-static spacer for a flexible printed circuit board comprising: a spacer base material film for the flexible printed circuit board; and an anti-static layer formed on the base material film, wherein the transparent permanent anti-static spacer is fabricated by performing an embossing, wherein the anti-static layer is formed by coating an anti-static solution comprising one or more metal oxides and one or more organic or inorganic binders as effective ingredients, and drying it to thereby provide a permanent anti-static property and a mold releasing property on the surface of the spacer, and the spacer can be used in a high temperature process.

2: The transparent permanent anti-static spacer for a flexible printed circuit board according to claim 1, wherein the anti-static coating solution for the anti-static layer further comprises an additive for supplying the releasing property.

3: The transparent permanent anti-static spacer for a flexible printed circuit board according to claim 1, wherein the metal oxide is selected from an indium oxide, a tin oxide, a titanium oxide, and the like, which have an average particle diameter of below 2 μm.

4: The transparent permanent anti-static spacer for a flexible printed circuit board according to claim 1, wherein a particle shape of the metal oxide is spherical, fiber, or flake with an aspect ratio(a ratio of the longer part to the shorter part) of higher than 1.

5: The transparent permanent anti-static spacer for a flexible printed circuit board according to claim 1, wherein the conductivity of the metal oxide is in a range of 10⁻¹˜10⁵ Ω·cm

6: The transparent permanent anti-static spacer for a flexible printed circuit board according to claim 1, wherein the binder is organic binder and is made by using at least one organic binder having a functional group, such as an urethane, an acryl, an ester, an epoxy, an amide, an imide, a hydroxyl group, a carboxyl group, a styrene group, a carbonate group, a vinyl-acetate group, and the like, or the binder is made by using a copolymer binder mixed with more than one functional group, such as an ester-ether, an acryl-urethane, an acryl-epoxy, an urethane-epoxy.

7: The transparent permanent anti-static spacer for a flexible printed circuit board according to any one of claim 1, wherein the binder is made by further adding more than any one of a melamine, an isocyanate, an epoxy curing agent, and a weak acid, and the like, and curing them.

8: The transparent permanent anti-static spacer for a flexible printed circuit board according to claim 1, wherein the binder is an inorganic binder selected from a silicate, a titanate.

9: The transparent permanent anti-static spacer for a flexible printed circuit board according to claim 1, wherein the binder is an ultraviolet ray curing binder and is a mixture made by mixing 2 to 15 functional group acrylate/metacrylate oligomer, 1 to 6 functional group acrylate/metacrylate monomer, and an initiator.

10: The transparent permanent anti-static spacer for a flexible printed circuit board according to claim 1 or, wherein the anti-static layer is corona-treated to provide the surface tension of higher than 35 dynes/cm², or is formed with a primer layer so as to increase the adhesion force imparted to the base material film of the spacer.

11: The transparent permanent anti-static spacer for a flexible printed circuit board according to claim 2, wherein the additive for supplying the releasing property is selected from a silicone group, a fluorine group, and an acryl group.

12: The transparent permanent anti-static spacer for a flexible printed circuit board according to claim 1, wherein the base material film is a film (sheet) made by comprising at least one selected from the polymers, having a temperature of above 150° C., such as a polyimide, a polyether-imide, a polyether-sulfone, an cyclo olefin compound, a polyphenylene oxide, high temperature polycarbonate as effective ingredients, or comprising a modified polymer made from the polymers as effective ingredients, or comprising modified polymerized copolymers as effective ingredients.

13: The transparent permanent anti-static spacer for a flexible printed circuit board according to claim 2, wherein the metal oxide is selected from an indium oxide, a tin oxide, a titanium oxide, and the like, which have an average particle diameter of below 2 μm.

14: The transparent permanent anti-static spacer for a flexible printed circuit board according to claim 2, wherein a particle shape of the metal oxide is spherical, fiber, or flake with an aspect ratio(a ratio of the longer part to the shorter part) of higher than 1.

15: The transparent permanent anti-static spacer for a flexible printed circuit board according to claim 2, wherein the conductivity of the metal oxide is in a range of

16: The transparent permanent anti-static spacer for a flexible printed circuit board according to claim 2, wherein the binder is organic binder and is made by using at least one organic binder having a functional group, such as an urethane, an acryl, an ester, an epoxy, an amide, an imide, a hydroxyl group, a carboxyl group, a styrene group, a carbonate group, a vinyl-acetate group, and the like, or the binder is made by using a copolymer binder mixed with more than one functional group, such as an ester-ether, an acryl-urethane, an acryl-epoxy, an urethane-epoxy.

17: The transparent permanent anti-static spacer for a flexible printed circuit board according to any one of claim 2, wherein the binder is made by further adding more than any one of a melamine, an isocyanate, an epoxy curing agent, and a weak acid, and the like, and curing them.

18: The transparent permanent anti-static spacer for a flexible printed circuit board according to claim 2, wherein the binder is an inorganic binder selected from a silicate, a titanate.

19: The transparent permanent anti-static spacer for a flexible printed circuit board according to claim 2, wherein the binder is an ultraviolet ray curing binder and is a mixture made by mixing 2 to 15 functional group acrylate/metacrylate oligomer, 1 to 6 functional group acrylate/metacrylate monomer, and an initiator.

20: The transparent permanent anti-static spacer for a flexible printed circuit board according to claim 2, wherein the anti-static layer is corona-treated to provide the surface tension of higher than 35 dynes/cm² , or is formed with a primer layer so as to increase the adhesion force imparted to the base material film of the spacer.
